(19) United States
(12) Patent Application Publication
(10) Pub. No.: US 2009/0039373 A1
(43) Pub. Date: Feb. 12, 2009

(54) Group III nitride-based compound semiconductor light emitting device

(75) Inventors: Yoshiki Saito, Aichi-ken (JP); Takayoshi Yajima, Aichi-ken (JP); Yasuhisa Ushida, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/219,455

(22) Filed: Jul. 22, 2008

(30) Foreign Application Priority Data
Jul. 24, 2007 (JP) 2007-191510

(51) Int. Cl. H01L 33/00

(52) U.S. Cl. 257/98; 257/E33.067

(57) ABSTRACT

A group III nitride-based compound semiconductor light emitting device includes a polarity inversion layer including a surface with a convex portion, and a transparent electrode formed on the polarity inversion layer. The polarity inversion layer may have a magnesium concentration of not less than 1×10²⁰ atoms/cm³, or not less than 2×10²⁰ atoms/cm³ and not more than 5×10²¹ atoms/cm³. The polarity inversion layer may be formed of AlₓGa₁₋ₓN (0≦x<1) doped with magnesium.

The present application is based on Japanese patent application No. 2007-191510 filed on Jul. 24, 2007, the entire contents of which are incorporated herein by reference.

### BACKGROUND OF THE INVENTION

1. Field of the Invention

This invention relates to a group III nitride-based compound semiconductor light emitting device. Herein, the group III nitride-based compound semiconductor light emitting device includes a semiconductor of AlₓGa_{y}In_{1-x-y}N (x, y and x+y are all not less than 0 and not more than 1) and doped with arbitrary element to have n-type/p-type conductivity. Further, it includes a semiconductor that a part of group III element or group IV element thereof is replaced by B, Tl, P, As, Sb or Bi.

2. Description of the Related Art

The group III nitride-based compound semiconductor light emitting device is generally formed by conducting epitaxial growth on a heterosubstrate by MOVPE, where film thickness thereof increases in a c-axis direction with so-called “Ga polarity”. Here, the surface of the epitaxial film corresponds to a c-plane.

Also, when a GaN substrate with a c-plane as a main plane is used for epitaxial growth by MOVPE, the c-plane of the GaN substrate with “Ga polarity” is generally used in terms of the crystalline quality, electrical characteristics and optical characteristics. In this case, the epitaxial growth film is grown such that film thickness thereof increases in a c-axis direction with “Ga polarity”. In contrast, it is not advantageous to use a c-plane with “N polarity”, where it is difficult to obtain a uniform epitaxial growth film and the crystal is likely to be a crude crystal.

JP-A-2003-101149 discloses a technique that the polarity of an epitaxial growth film is inverted into “N polarity” from “Ga polarity”. Herein, the polarity inversion means that completely “Ga polarity” at the whole surface of an epitaxial film is modified to “N polarity” at a part (e.g., in many microscopic regions) of the surface of the epitaxial film except completely “N polarity” at the whole surface of the epitaxial film.

JP-A-06-291368 discloses a technique that a p-type layer is provided with a concavity and convexity surface for enhancing the light extraction efficiency of a light emitting device.

Many techniques other than JP-A-06-291368 are also proposed that a p-type layer or a surface of positive electrode is provided with a concavity and convexity surface for enhancing the light extraction efficiency of a light emitting device. However, the surface of the p-type layer is a final plane, i.e., a plane with “Ga polarity”, formed by growth in the c-axis direction. The c-plane of “Ga polarity” exhibits high resistance to wet etching with acid or alkali solution and is therefore difficult to wet-etch to form the concavity and convexity surface thereon.

The following methods are used for forming the concavity and convexity surface by the wet etching.

A heterosubstrate after used for epitaxial growth is lifted off and “N polarity” side as a c-plane previously contacting the heterosubstrate is thereby exposed. Then, the “N polarity” side (typically a negative electrode side) is wet-etched to form the concavity and convexity surface.

Alternatively, a GaN substrate with a c-plane as a main plane is used to conduct epitaxial growth by MOVPE. Then, an N polarity side opposite a surface (i.e., a Ga polarity side of the GaN substrate) used for the epitaxial growth is wet-etched to form the concavity and convexity surface. Also in this case, the GaN substrate (i.e., the N polarity side) is typically on the negative electrode side.

In forming the concavity and convexity surface on the growth surface during the epitaxial growth, the formation condition must be far off an optimum condition for having an epitaxial film good in crystalline quality. Therefore, the device characteristics are bound to deteriorate and, especially, the drive voltage inevitably increases.

### SUMMARY OF THE INVENTION

It is an object of the invention to provide a group III nitride-based compound semiconductor light emitting device that has enhanced light extraction efficiency.

(1) According to one embodiment of the invention, a group III nitride-based compound semiconductor light emitting device comprises:

a polarity inversion layer including a surface comprising a convex portion; and

a transparent electrode formed on the polarity inversion layer. in the above embodiment (1), the following modifications and changes can be made.

(i) The polarity inversion layer comprises a magnesium concentration of not less than 1×10²⁰ atoms/cm³.

(ii) The polarity inversion layer comprises a magnesium concentration of not less than 2×10²⁰ atoms/cm³ and not more than 5×10²¹ atoms/cm³.

(iii) The polarity inversion layer comprises AlₓGa₁₋ₓN (0≦x<1) doped with magnesium.

(iv) The surface comprising the convex portion is formed by wet etching that uses one of phosphoric acid, potassium hydride and tetramethylammonium hydroxide.

(v) The surface comprises the convex portion of about 1×10⁷/cm² to about 1×10¹⁰/cm².

(vi) The surface comprises the convex portion of about 1×10⁸/cm² to about 1×10⁹/cm².

(vii) The surface comprises the convex portion at a Ga polarity region and a concave portion at a N polarity region.

(viii) The light emitting device further comprises:

an emission layer; and

a light extraction surface for extracting light emitted from the emission layer,

wherein the polarity inversion layer is formed nearer the light extraction surface in relation to the emission layer.

### ADVANTAGES OF THE EMBODIMENT

By excessively increasing the concentration of magnesium added as an acceptor doping impurity, a polarity inversion region can be sufficiently formed. The polarity inversion region includes a number of microscopic regions having “N polarity” yielded on c-plane to have normally “Ga polarity” in case of ordinary epitaxial growth in the c-axis direction.

The microscopic regions having “N polarity” are easy to etch by wet etching and therefore a number of etched pits can be formed by wet etching. Thus, a p-type layer with a number of the etched pits (i.e., with a number of concavities and convexities) is formed and a transparent positive electrode is formed on the p-type layer. As a result, a face-up type group III nitride-based compound semiconductor light emitting device can be easy formed that is enhanced in light extraction efficiency through the transparent positive electrode.

The invention can be also applied to a heterosubstrate such as a sapphire substrate and an expensive GaN substrate is not always required in the invention. Further, a step for removing an epitaxial growth substrate by lift-off is not required in the invention and therefore the fabrication cost of the light emitting device of the invention can be reduced.

### BRIEF DESCRIPTION OF THE DRAWINGS

The preferred embodiments according to the invention will be explained below referring to the drawings, wherein:

FIGS. 1A to 1C are AFM (atomic force microscope) analysis images showing the surface of three wafers, before wet etching, that a GaN layer is formed different in Mg concentration thereof in Example 1 of a preferred embodiment according to the invention;

FIG. 2A to 2C are AFM (atomic force microscope) analysis images showing the surface of three wafers, after wet etching, that a GaN layer is formed different in Mg concentration thereof in Example 1 of the preferred embodiment according to the invention; and

FIG. 3 is a cross sectional view showing a group III nitride-based compound semiconductor light emitting device 100 in Example 2 of the preferred embodiment according to the invention.

### DETAILED DESCRIPTION OF THE PREFERRED EMBODIMENTS

In order to form a polarity inversion region of the invention, magnesium (Mg) is preferably added not less than 1×10²⁰ atoms/cm³, more preferably not less than 2×10²⁰ atoms/cm³, and still more preferably 5×10²⁰ atoms/cm³. If the additive amount of Mg exceeds 5×10²¹ atoms/cm³, the Mg atoms exist more than 1/10 of Ga atoms where such a layer cannot be regarded as a group III nitride-based compound semiconductor. Also, the electrical conductivity deteriorates such that the layer does not function as an electrode formation.

The thickness of a polarity inversion layer is preferably not less than 0.1 μm and more preferably not less than 0.3 μm. Thereby, a concavity and convexity with a large difference can be formed by wet etching. On the other hand, if the thickness of the polarity inversion layer exceeds 1 μm, the resistivity of the polarity inversion layer increases to cause a too-high drive voltage. Therefore, such a thickness is not preferable.

Area of N polarity to be etched is preferably not less than 20% of the whole surface, more preferably not less than 30%, and more preferably not less than 40% thereof.

The group III nitride-based compound semiconductor light emitting device of invention is characterized in that it includes a transparent electrode and an uppermost layer forming the transparent electrode is composed of a polarity inversion layer that includes a concavity and convexity formed by wet etching. No limitations is required to the other composition of the light emitting device, fabrication method of each layer etc.

For example, an emission layer or active layer may be a single layer, a single quantum well (SQW) structure, multiquantum well (MQW) structure etc. When cladding layers are formed on the p-side or n-side of the emission layer or active layer, one or both of them may be a multilayer structure. In application to a laser structure, a guide layer or current blocking structure may be formed and an insulating layer may be formed on any surface or inside thereof. Further, a layer for improvement in electrostatic discharge resistance may be formed.

### EXAMPLE 1

Formation of concavity and convexity by wet etching to a polarity inversion layer is tested as below.

An a-plane sapphire substrate is provided, and a GaN:Mg layer with a thickness of 300 nm is formed through an AlN buffer layer on the substrate. By controlling the flow rate of biscyclopentadienyl magnesium (Cp₂Mg) as a magnesium source, three kinds of wafer are formed that are 5×10¹⁹/cm³, 1.5×10²⁰/cm³ and 2.5×10²⁰/cm³, respectively, in doping amount of magnesium.

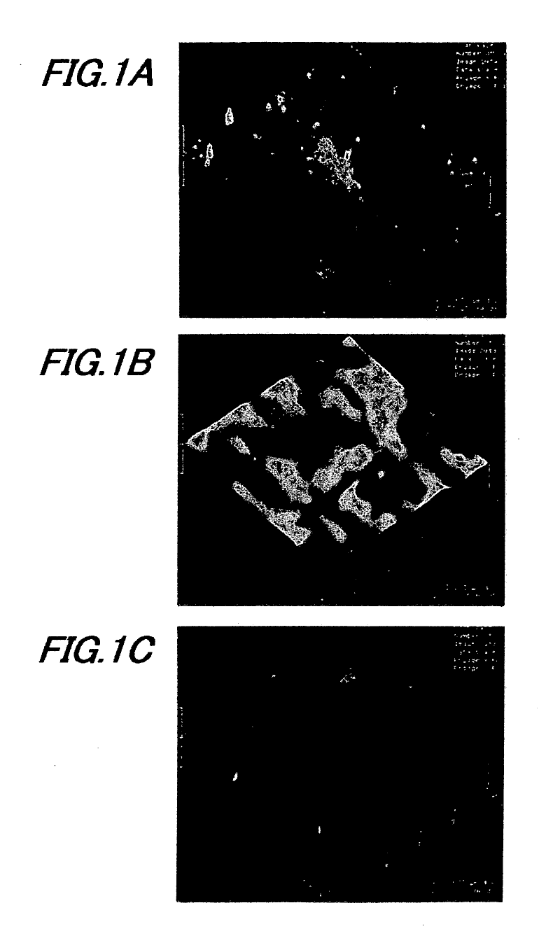

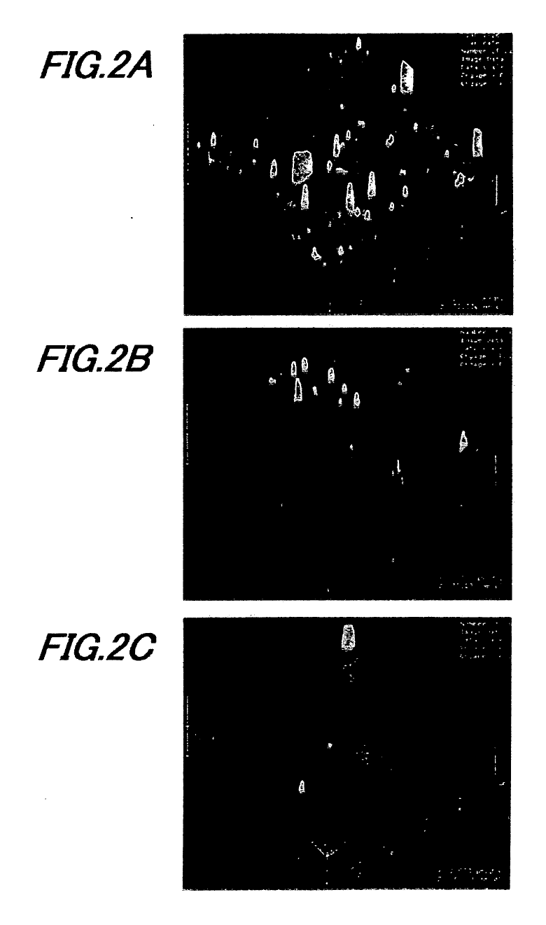

The three wafers are analyzed in terms of surface morphology before/after wet etching by potassium hydroxide (KOH) by AFM (atomic force microscope) image. The results are as shown in FIGS. 1A to 1C and FIGS. 2A to 2C.

FIG. 1A is an AFM image of a wafer surface before wet etching at a magnesium doping amount of 2.5×10²⁰/cm³, and FIG. 2A is an AFM image of the wafer surface after wet etching.

FIG. 1B is an AFM image of a wafer surface before wet etching at a magnesium doping amount of 1.5×10²⁰/cm³, and FIG. 2B is an AFM image of the wafer surface after wet etching.

FIG. 1C is an AFM image of a wafer surface before the wet etching at a magnesium doping amount of 5×10¹⁹/cm³, and FIG. 2C is an AFM image of the wafer surface after wet etching.

In case of 2.5×10²⁰/cm³ in magnesium doping amount, many convex parts are, as shown in FIG. 1A, observed on the wafer surface already before wet etching. As shown in FIG. 2A, after wet etching, convex parts are observed 7×10⁸/cm².

In case of 1.5×10²⁰/cm³ in magnesium doping amount, no convex parts is, as shown in FIG. 1B, observed on the wafer surface before wet etching. As shown in FIG. 2B, after wet etching, convex parts are observed 1.6×10⁸/cm².

In case of 5×10¹⁹/cm³ in magnesium doping amount, no convex parts is, as shown in FIG. 1C, observed on the wafer surface before wet etching. As shown in FIG. 2C, after wet etching, convex parts are observed 7×10⁶/cm².

Thus, it is found that when the magnesium doping amount exceeds 1×10²⁰/cm³, many convex parts are formed about 1×10⁷/cm² to about 1×10¹⁰/cm² after wet etching.

In other words, when the magnesium doping amount exceeds 1×10²⁰/cm³, many microscopic regions exhibiting N-polarity are formed. Thereby, since the N-polarity regions can be easy etched by wet etching, the concavity and convexity can be easy formed on the surface of the p-layer. Accordingly, the convex parts on the surface of the p-layer are formed preferably about 1×10⁷/cm² to about 1×10¹⁰/cm², more preferably about 1×10⁸/cm² to about 1×10⁹/cm² after wet etching so as to enhance light extraction efficiency.

In contrast, if the magnesium doping amount is less than 1×10²⁰/cm³, only small number of convex parts are formed even after wet etching. This indicates that the microscopic regions exhibiting N-polarity are few formed and therefore the wet etching is still difficult to conduct, where the concavity and convexity cannot be easy formed on the surface of the p-layer.

### EXAMPLE 2

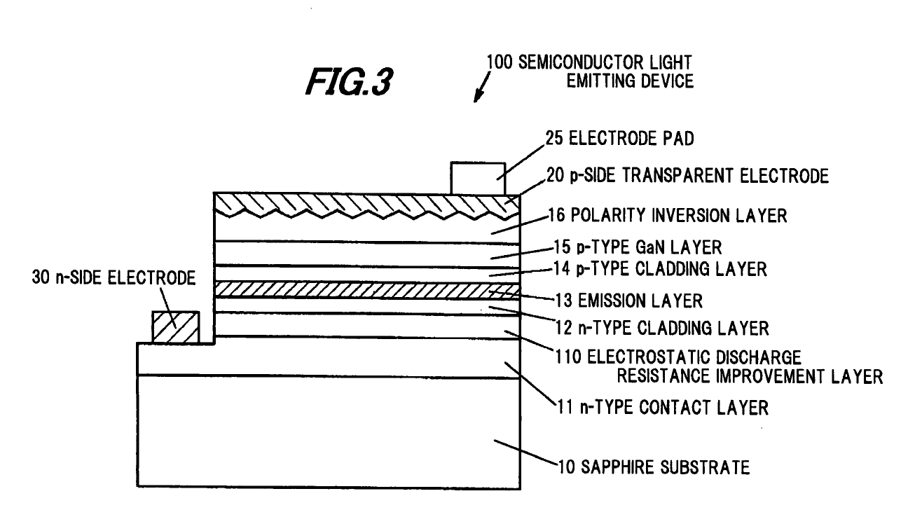

FIG. 3 is a cross sectional view showing a group III nitride-based compound semiconductor light emitting device 100 in a preferred embodiment of the invention.

The group III nitride-based compound semiconductor light emitting device 100 is constructed such that about 15 nm thick buffer layer (not shown) of aluminum nitride (AlN) is formed on a sapphire substrate 10, and about 15 nm thick n-type contact layer 11 of GaN with silicon (Si) doped is formed thereon. On the n-type contact layer 11, electrostatic discharge resistance improvement layer 110 in multilayer structure is formed that is composed of 300 nm thick undoped GaN layer and 30 nm thick silicon doped GaN layer. On the electrostatic discharge resistance improvement layer 110, about 74 nm thick n-type cladding layer 12 in multilayer structure is formed that is composed of ten units of undoped In_{0.1}Ga_{0.9}N, undoped GaN and silicon doped GaN.

On the n-type cladding layer 12, emission layer 13 in MQW structure is formed that is composed of seven pairs of about 3 nm thick In_{0.25}Ga_{0.75}N well layer and about 3 nm thick GaN barrier layer which are alternately stacked. On the emission layer 13, about 33 nm thick p-type cladding layer 14 in multilayer structure is formed that is composed of p-type Al_{0.3}Ga_{0.7}N and p-type Al_{0.08}Ga_{0.92}N. On the p-type cladding layer 14, p-type GaN layer 15 and polarity inversion layer 16 are formed. The polarity inversion layer 16 has concavity and convexity formed by wet etching as detailed later.

Further, a (p-side) transparent electrode 20 of ITO (indium tin oxide) is formed on the polarity inversion layer 16 and an n-side electrode 30 is formed on an exposed surface of the n-type contact layer 11. The n-side electrode 30 is composed of about 20 nm thick vanadium (V) and about 2 μm thick aluminum (Al). On the transparent electrode 20, an electrode pad 25 of gold (Au) alloy is partially formed.

The group III nitride-based compound semiconductor light emitting device 100 in FIG. 3 is fabricated as below.

Gases used therein are ammonium (NH₃), carrier gas (H₂, N₂), trimethylgallium (TMG), trimethylaluminum (TMA), trimethylindium (TMI), silane (SiH₄) and cyclopentadienyl magnesium (Cp₂Mg).

First, a single crystal sapphire substrate 10 is provided that is as a main plane provided with a-plane and cleaned by organic solvent cleaning and heat treatment. Then, it is attached to a susceptor provided in a reactor chamber of MOCVD apparatus. Then, the sapphire substrate 10 is baked at 1100° C. under ordinary pressure while supplying H₂ at a flow rate of 2 L/min (L: liter) about 30 min into the reactor chamber.

Then, temperature is reduced to 400° C. and the AlN buffer layer is formed about 15 nm thick by supplying H₂ at 20 L/min, NH₃ at 20 L/min and TMA at 1.8×10⁻⁵ mol/min for about 1 min.

Then, the temperature of the sapphire substrate 10 is kept at 1150° C. and the n-type contact layer 11 is formed by supplying H₂ at 20 L/min, NH₃ at 10 L/min, TMG at 1.7×10⁻⁴ mol/min and silane diluted to 0.86 ppm by H₂ gas at 20×10⁻⁸ mol/min for 40 min. The n-type contact layer 11 is formed of n-type GaN with a silicon concentration of 4×10¹⁸/cm³.

Then, the temperature of the sapphire substrate 10 is kept at 850° C. and the electrostatic discharge resistance improvement layer 110 in double layer is formed by, changing the carrier gas into N₂ gas, growing sequentially 300 nm thick i-GaN layer and 30 nm thick n-type GaN layer with a silicon concentration of 4×10¹⁸/cm³.

Then, the n-type cladding layer 12 in multilayer structure is formed about 74 nm thick by supplying N₂ or H₂ at 10 L/min, NH₃ at 10 L/min and changing the supply of TMG, TMI and silane diluted to 0.86 ppm by H₂ gas, where the multiplayer is composed of ten units of undoped In_{0.1}Ga_{0.9}N, undoped GaN (which are grown at a sapphire substrate temperature of 800° C.) and silicon doped GaN (which is grown at a sapphire substrate temperature of 840° C.).

After the n-type cladding layer 12 is formed, by changing the supply of TMG, TMI, the emission layer 13 in MQW structure is formed that is composed of seven pairs of about 3 nm thick In_{0.25}Ga_{0.75}N well layer (which is grown at a sapphire substrate temperature of 720° C.) and about 3 nm thick GaN barrier layer (which is grown at a sapphire substrate temperature of 885° C.) which are alternately stacked.

Then, the about 33 nm thick p-type cladding layer 14 in multilayer structure is formed that is composed of p-type Al_{0.3}Ga_{0.7}N and p-type Al_{0.08}Ga_{0.92}N by supplying N₂ or H₂ at 10 L/min, NH₃ at 10 L/min and changing the supply of TMG, TMI, TMA and Cp₂Mg and keeping the temperature of the sapphire substrate 10 at 840° C.

Then, the 50 nm thick p-type GaN layer 15 with a magnesium concentration of 5×10¹⁹/cm³ and the 150 nm thick polarity inversion layer 16 with a magnesium concentration of 5×10²⁰/cm³ are formed by supplying N₂ or H₂ at 20 L/min, NH₃ at 10 L/min and changing the supply of TMG and Cp₂Mg and keeping the temperature of the sapphire substrate 10 at 1000° C.

Then, wet etching by KOH solution is conducted such that concavity and convexity is formed on the polarity inversion layer 16. Thereby, difference in concavity and convexity comes up to 100 nm.

Then, a photoresist is coated on the polarity inversion layer 16, and a window at predetermined regions is formed by photolithography. Then, reactive ion etching is conducted by using chlorine-containing gas to a part of the polarity inversion layer 16 being not masked, the p-type GaN layer, the p-type cladding layer 14, the emission layer 13, the n-type cladding layer 12 and n-type GaN layer 11, so as to expose the surface of the n-type GaN layer. Then, after removing the resist mask, the n-side electrode 30 on the n-type GaN layer 11 and the p-side electrode 20 on the polarity inversion layer 16 are formed as below.

The transparent electrode 20 of ITO is formed 200 nm thick on the entire surface of the wafer. Then, a photoresist (mask) is coated thereon, the mask of the p-side electrode 20 is patterned by photolithography, and the p-side electrode 20 is shaped in a desired form by dry etching.

Then, a photoresist is coated, and a window at predetermined regions is formed by photolithography. The n-side electrode 30 is formed on the n-type GaN layer 11 by vacuum deposition at high vacuum lower than 10⁻⁶ Torr.

Then, the photoresist is removed by lift-off and the n-side electrode 30 is shaped in a desired form. Then, heat treatment at 600° C. for 5 min is conducted in nitrogen containing atmosphere for alloying the n-side electrode 30 with the n-type GaN layer 11 as well as reducing the resistivity of the polarity inversion layer 16, the p-type GaN layer 15 and the p-type classing layer 14.

The group III nitride-based compound semiconductor light emitting device in FIG. 3 thus fabricated can be significantly enhanced in ratio of light output to power consumption as compared to a light emitting device without the polarity inversion layer 16.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A group III nitride-based compound semiconductor light emitting device, comprising:
a polarity inversion layer including a surface comprising a convex portion; and
a transparent electrode formed on the polarity inversion layer.

2. The light emitting device according to claim 1, wherein:
the polarity inversion layer comprises a magnesium concentration of not less than 1×10²⁰ atoms/cm³.

3. The light emitting device according to claim 1, wherein:
the polarity inversion layer comprises a magnesium concentration of not less than 2×10²⁰ atoms/cm³ and not more than 5×10²¹ atoms/cm³.

4. The light emitting device according to claim 1, wherein:
the polarity inversion layer comprises AlₓGa₁₋ₓN (0≦x<1) doped with magnesium.

5. The light emitting device according to claim 1, wherein:
the surface comprising the convex portion is formed by wet etching that uses one of phosphoric acid, potassium hydride and tetramethylammonium hydroxide.

6. The light emitting device according to claim 1, wherein:
the surface comprises the convex portion of about 1×10⁷/cm² to about 1×10¹⁰/cm².

7. The light emitting device according to claim 1, wherein:
the surface comprises the convex portion of about 1×10⁸/cm² to about 1×10⁹/cm².

8. The light emitting device according to claim 1, wherein:
the surface comprises the convex portion at a Ga polarity region and a concave portion at a N polarity region.

9. The light emitting device according to claim 1, further comprising:
an emission layer; and
a light extraction surface for extracting light emitted from the emission layer,
wherein the polarity inversion layer is formed nearer the light extraction surface in relation to the emission layer.
